(19) United States
(12) Patent Application Publication
(10) Pub. No.: US 2010/0288531 A1
(43) Pub. Date: Nov. 18, 2010

(54) TRANSPARENT CONDUCTIVE FILM, METHOD OF MANUFACTURING TRANSPARENT CONDUCTIVE FILM, AND TRANSPARENT ELECTRODE FOR ELECTRONIC DEVICE

(75) Inventors: Hirokazu KOYAMA, Tokyo (JP); Masaki GOTO, Tokyo (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA HOLDINGS, INC., Tokyo (JP)

(21) Appl. No.: 12/770,364

(22) Filed: Apr. 29, 2010

(30) Foreign Application Priority Data
May 12, 2009 (JP) 2009115334

(51) Int. Cl. H01B 5/00; B05D 5/12; B32B 27/04

(52) U.S. Cl. 174/126.2; 427/123; 427/98.4; 428/297.4

(57) ABSTRACT

Provided is a transparent conductive film exhibiting high conductivity together with excellent transparency, and also exhibiting film strength tolerant to a washing treatment and a pattern forming treatment while maintaining conduction to an electronic device layer formed on an transparent conductive layer. Also disclosed is a method of manufacturing a transparent conductive film possessing a transparent substrate and provided thereon, a transparent conductive layer containing a metal nanowire, possessing the steps of forming a layer containing a crosslinking agent on the substrate, coating a coating solution containing a metal nanowire onto the layer containing the crosslinking agent, drying the coating solution, and conducting a treatment by which the crosslinking agent is reacted.

This application claims priority from Japanese Patent Application No. 2009-115334 filed on May 12, 2009, which is incorporated hereinto by reference.

### TECHNICAL FIELD

The present invention relates to a transparent conductive film having a transparent conductive layer, which is suitably employed for a transparent electrode usable for a liquid crystal display element, an organic light-emitting element, an inorganic electric field light-emitting element, a solar cell, an electromagnetic wave shield, a touch panel, and an electronic paper sheet; specifically to a transparent conductive film having a transparent conductive layer having been subjected to a crosslinking treatment, which is tolerant to a washing treatment and a pattern forming treatment when such the transparent conductive layer is used as an electrode, and more specifically to a transparent conductive film exhibiting no inhibition of conductivity on the surface of a transparent conductive layer even during such the crosslinking treatment.

### BACKGROUND

The transparent conductive film is utilized for transparent electrodes for electronic devices such as a liquid crystal display, an electroluminescence display, a plasma display, an electrochromic display, a solar cell, a touch panel, and an electronic paper sheet, and utilized for electromagnetic wave shield material.

As the transparent conductive material, metal oxides, for example, are conventionally used, specific examples thereof include tin or zinc-doped indium oxides (ITO and IZO), aluminum or gallium-doped zinc oxides (AZO and GZO), and fluorine or antimony-doped tin oxides (HD and ATO). In preparation of metal oxide transparent conductive layers, a vapor deposition film forming method such as a vacuum evaporation method, a sputtering method, an ion plating method or the like is generally utilized. However, a large-scale and intricately designed apparatus is to be arranged since these film forming methods are used in vacuum, and technology and development capable of reducing manufacturing cost as well as environmental load have been demanded since a large amount of energy is consumed for the film formation. Further, on the other hand, as typified by a liquid crystal display and a touch panel display, a larger area of the transparent conductive material is desired, and in line with this, light weight and flexibility of the transparent conductive material have been highly demanded. Further, the transparent electrode having a large area has been desired to have lower resistance since it undergoes influence of a voltage drop.

In this case, it is reported that a nanowire made of a metal element having a conductivity of at least 1×10⁷ S/m in a bulk state can be prepared by each of various methods such as liquid phase methods and vapor deposition methods. For example a method of manufacturing an Ag nanowire can be cited in Non-patent Document 1. Specifically, as a technique of a transparent conductive material used for a low resistance high transparent conductive film, a method to use a metal nanowire as a conductor, and a method of coating an overcoat layer made of a prepolymer onto a metal nanowire layer, followed by curing are disclosed (refer to Patent Document 1). This method is a preferred method since a low resistance high transparent conductive film can be obtained via coating.

Incidentally, when applying a transparent conductive film to an electrode for an electronic device, a pattern forming treatment is often carried out, and a washing treatment is also conducted in order to inhibit defects caused by fine dust during formation of an electronic device layer. However, the transparent conductive film is destroyed via such the pattern forming treatment and washing treatment when no overcoat layer is present. On the other hand, when a process tolerant to such the treatment is conducted after forming the overcoat layer, the surface of the metal nanowire is covered by such the process, whereby there has appeared a problem in electricity application in cases where a layer is provided on the transparent conductive film in the electronic device.

(Patent Document 1) U.S. Patent No. 2007/0074316 A1

(Non-Patent Document) Adv. Mater. 2002, 14, 833-837

### SUMMARY

It is an object of the present invention to provide a transparent conductive film exhibiting high conductivity together with excellent transparency, and also exhibiting film strength tolerant to a washing treatment and a pattern forming treatment while maintaining conduction to an electronic device layer formed on an transparent conductive layer.

### DESCRIPTION OF THE PREFERRED EMBODIMENTS

The above object of the present invention is accomplished by the following structures.

(Structure 1) A method of manufacturing a transparent conductive film comprising a transparent substrate and provided thereon, a transparent conductive layer comprising a metal nanowire, comprising the steps of forming a layer comprising a crosslinking agent on the substrate, coating a coating solution comprising a metal nanowire onto the layer comprising the crosslinking agent, drying the coating solution, and conducting a treatment by which the crosslinking agent is reacted.

(Structure 2) The method of Structure 1, wherein the treatment is a heat treatment.

(Structure 3) The method of Structure 1 or 2, wherein the coating solution comprises a polymer comprising a group capable of conducting reaction with the crosslinking agent.

(Structure 4) The method of any one of Structures 1-3,

wherein the layer comprising the crosslinking agent comprises a polymer comprising a group capable of conducting reaction with the crosslinking agent.

(Structure 5) The method of any one of Structures 1-4,

wherein the crosslinking agent is soluble in a solvent for the coating solution.

(Structure 6) The method of any one of Structures 1-5, comprising the step of pattern-forming the transparent conductive layer via a pattern forming treatment.

(Structure 7) The method of any one of Structures 1-6, comprising the step of conducting a washing treatment for the transparent conductive layer.

(Structure 8) A transparent conductive film comprising a transparent substrate and provided thereon, a layer comprising a crosslinking agent, and a layer comprising a nanowire, further provided on the layer comprising a crosslinking agent.

(Structure 9) A transparent conductive film prepared by the method of manufacturing a transparent conductive film of any one of Structures 1-7.

(Structure 10) A transparent electrode comprising electronic device patterns of the transparent conductive film of Structure 8 or 9.

While the preferred embodiments of the present invention have been described using specific terms, such description is for illustrative purposes only, and it is to be understood that changes and variations may be made without departing from the spirit or scope of the appended claims.

### DETAILED DESCRIPTION OF THE INVENTION

In the present invention, it is assumed that a crosslinking agent is diffused to a transparent conductive layer from an auxiliary layer (a layer containing the crosslinking agent) provided between a substrate and the transparent conductive layer containing metal nanowires to form a crosslinking film. In this case, a large amount of the crosslinking agent is present on the side close to the layer containing the crosslinking agent in relation to the transparent conductive layer, whereby a strong crosslinking agent is formed, whereas a small amount of the crosslinking agent is diffused on the surface side close to the side where an electronic device layer is provided (the side distant from the layer containing the crosslinking agent in relation to the transparent conductive layer), and it would appear that film strength and conduction can be compatible because of no inhibition of electricity application via difficult formation of the crosslinking film covering a metal nanowire.

Next, constituent elements of the present invention and preferred embodiments of the present invention will be described in detail, but the present invention is not limited thereto.

### [Metal Nanowire]

Metal nanowire is generally referred to as a line-shaped structural substance made of a metal element as a principal structural element. The metal nanowire of the present invention means a line-shaped structural substance having a diameter in nanometer size.

A metal composition of metal nanowire of the present invention is not specifically limited, and can be composed of one kind or plural kinds of noble metal elements or base metal elements, but at least one selected from the group consisting of noble metals such as gold, platinum, silver, palladium, rhodium, iridium, ruthenium and osmium, iron, cobalt, copper and tin is/are preferably included, and at least silver is more preferably included in view of conductivity.

Further, in order to make conductivity and stability (resistance to sulfurization and oxidation of nanowire, and migration resistance of metal nanowire) to be compatible, it is also preferable to contain silver and at least one metal belonging to noble metals other than silver. When the metal nanowire of the present invention contains at least two metal elements, a metal composition of the surface of a metal nanowire may be different from a metal composition inside the metal nanowire, and the entire nanowire may have an identical metal composition.

In the present invention, a method of manufacturing metal nanowires is not specifically limited, and commonly known methods such as a liquid phase method or a vapor deposition method, for example, are usable. In addition, the specific manufacturing method is not also specifically limited, and commonly known manufacturing methods are also usable. For example, a method of manufacturing Ag nanowires may be cited in Adv. Mater. 2002, 14, 833-837 and Chem. Mater. 2002, 14, 4736-4745; a method of manufacturing Au nanowires may be cited in Japanese Patent O.P.I. Publication No. 2006-233252; a method of manufacturing Cu nanowires may be cited in Japanese Patent O.P.I. Publication No. 2002-266007; and a method of manufacturing Co nanowires may be cited in Japanese Patent O.P.I. Publication No. 2004-149871. The above-described method of manufacturing Ag nanowires cited in Adv. Mater. 2002, 14, 833-837 and Chem. Mater. 2002, 14, 4736-4745 is preferably suitable as a method of manufacturing metal nanowires of the present invention, since the Ag nanowires can be easily prepared in an aqueous system, and silver has the largest conductivity among metals.

In the present invention, metal nanowires are brought into contact with each other to form a three-dimensionally conductive network, and it becomes possible to generate high conductivity, and to transmit light through window portions of the conductive network where no metal nanowire is present, resulting in compatibility of high conductivity and high transparency.

### [Coating Solution Containing Metal Nanowire]

A coating solution containing metal nanowires is preferably used in combination with some kind of transparent resin in order to acquire dispersibility of the metal nanowire, and also to hold the metal nanowire in a film after coating, followed by drying, and resins thereof such as a polyester based resin, an acrylic resin, a polyurethane based resin, an acrylurethane based resin, a polycarbonate based resin, a cellulose based resin, a polyvinyl acetal based resin, and a polyvinyl alcohol based resin can be used singly or in combination. A polymer having a group capable of conducting reaction with a crosslinking agent in the crosslinking agent-containing layer formed on the after-mentioned substrate is preferable, since a very strong film can be found via reaction with a crosslinking agent to be diffused. The group to be reacted with a crosslinking agent is dependent on crosslinking agents, but a hydroxyl group, a carboxyl group, and an amino group, for example, are provided. Examples of specific compounds as the polymer having a group capable of conducting reaction with a crosslinking agent include polyvinyl alcohol PVA-203, PVA-224, and PVA-420 (produced by KUREHA Corp.), polyvinyl acetal BM-1, BM-S, BL-1, BL-10, BL-S, and KS-5 (produced by Sekisui Chemical Co., Ltd.), hydroxypropylmethyl cellulose 60SH-06, 60SH-06, 60SH-50, 60SH-4000, and 90SH-100 (produced by Shin-Etsu Chemical Co., Ltd.), methylcellulose SM-100 (produced by Shin-Etsu Chemical Co., Ltd.), cellulose acetate L-20, L-40, and L-70 (produced by Daicel Chemical Industries, Ltd.), carboxymethyl cellulose (produced by Daicel Chemical Industries, Ltd.), hydroxyethyl cellulose SP-200, and SP-600 (produced by Daicel Chemical Industries, Ltd.), an acrylic acid alkyl copolymer JURYMER AT-210, and AT-510 (produced by Toagosei Co., Ltd.), polyhydroxyethyl acrylate, and polyhydroxyethyl methacrylate.

### [Solvent]

Solvents used for a coating solution containing metal nanowires are not specifically limited, but examples thereof include water, organic solvents (foe example, alcohols such as methanol and so forth, ketones such as acetone and so forth, amides such as formamide and so forth, sulfoxides such as dimethylsulfoxide and so forth, esters such as ethyl acetate and so forth, and ethers) and mixed solvents thereof.

### [Coating]

As the coating method, commonly known coating methods are usable, and usable examples thereof include a roller coating method, a bar coating method, a dip coating method, a spin coating method, a casting method, a die coating method, a blade coating method, a gravure coating method, a curtain coating method, a spray coating method, and a doctor coating method. Examples of the printing method include commonly known methods such as a letterpress (typographic) printing method, a porous (screen) printing method, a planographic (offset) printing method, an intaglio (gravure) printing, a spray printing method, and an inkjet printing method.

### [Crosslinking Agent]

A crosslinking agent is contained in an auxiliary layer provided between a substrate and a transparent conductive layer containing metal nanowires. The crosslinking agent is not limited, and commonly known agents are usable, but a crosslinking agent diffusible to a metal nanowire layer is preferable. Since the crosslinking agent is possible to be crosslinked while it is diffused to the metal nanowire layer, a thermally crosslinkable crosslinking agent is preferably usable. As to a heat treatment, preferably usable is a material with which reaction is produced via the treatment carried out at 100-150° C. for one to about 60 minutes, depending on heat resistance of the substrate. As such the crosslinking agent, usable are commonly known crosslinking agents such as an epoxy based crosslinking agent, a carbodiimide based crosslinking agent, a melamine based crosslinking agent, an isocyanate based crosslinking agent, a cyclocarbonate based crosslinking agent, a hydrazine based crosslinking agent, and a formalin based crosslinking agent. A solvent is preferably used in combination in order to accelerate reaction.

Of these crosslinking agents, preferably usable are an epoxy based crosslinking agent, a melamine based crosslinking agent, and an isocyanate based crosslinking agent.

The epoxy based crosslinking agent employed in the present invention is a compound having at least two epoxy groups in the molecule. Examples of the epoxy based crosslinking agent include DECONAL EX313, DECONAL EX614B, DECONAL EX521, DECONAL EX512, DECONAL EX1310, DECONAL EX1410, DECONAL EX610U, DECONAL EX212, DECONAL EX622, and DECONAL EX721 (produced by Nagase ChemteX Corporation).

The carbodiimide based crosslinking agent employed in the present invention is a compound having at least two carbodiimide groups in the molecule. The carbodiimide compound is conventionally synthesized via condensation reaction of organic diisocyanate. Herein, an organic group of the organic diisocyanate used in synthesis of the carbodiimide compound in the molecule is not specifically limited, either an aromatic system or an aliphatic system, or a mixture system thereof is usable, but the aliphatic system is specifically preferable in view of reactivity.

As to the carbodiimide based crosslinking agent employed in the present invention, CAEBODILITE V-02-L2 (produced by Nisshinbo Inc.), for example, is available in the market as a commercially available product.

The melamine based crosslinking agent employed in the present invention is a compound having at least two methylol group in the molecule, and as an example of the melamine based crosslinking agent is provided. Further, examples of commercially available melamine crosslinking agents include BECKAMINE M-3, BECKAMINE FM-180, and BECKAMINE NS-19 (produced by Dainippon Ink and Chemicals, Inc.).

The isocyanate based crosslinking agent employed in the present invention is a compound having at least two isocyanate groups in the molecule. Examples of the isocyanate based crosslinking agents include toluene diisocyanate, xylene diisocyanate, and 1,5-naphthalene diisocyanate. Examples of the commercially available isocyanate include SUMIJULE N3300 (produced by Sumika Bayer Urethane Co., Ltd.), and CORONATE L and MILLIONATE MR-400 (produced by Nippon Polyurethane Industry Co., Ltd.), and these are usable.

The crosslinking agent of the present invention is preferably soluble in a solvent for a coating solution containing metal nanowires. “Being soluble” herein means that 0.5 g are dissolved in 100 g of a solvent at 20° C. As to the crosslinking agent in combination with a solvent, preferable is a combination of a crosslinking agent and a solvent, in which 1 g are dissolved in 100 g of a solvent at 20° C.

A layer containing a crosslinking agent, which is formed on a substrate may contain a polymer, and preferable is a polymer having a group capable of conduction reaction with the crosslinking agent. As to such a resin, the same resin as a resin used for a transparent conductive layer is usable.

### [Transparent Substrate]

The transparent substrate used for a transparent conductive film of the present invention is not specifically limited as long as it exhibits high transparency. For example, a glass substrate, a resin substrate, and a resin film are preferable in view of excellent hardness as a substrate, and easy preparation of a conductive layer formed on the substrate surface, but a transparent resin film is preferably used in view of lightweight and flexibility.

The transparent resin film preferably usable as a transparent substrate in the present invention is not specifically limited, material, shape, structure, and thickness thereof can be selected from those commonly known. Examples thereof include polyester based resin films such as polyethylene terephthalate (PET), polyethylene naphthalate (PEN) and modified polyesters; polyolefin based resin films such as a polyethylene (PE) resin film, a polypropylene (PP) resin film, a polystyrene resin film and cyclic olefin based resin; vinyl based resins such as polyvinyl chloride and polyvinylidene chloride; a polyether ether ketone (PEEK) resin film; a polysulfone (PSF) resin film; a polyether sulfone (PES) resin film; a polycarbonate (PC) resin film; a polyamide resin film; a polyimide resin film; an acrylic resin film; and a triacetyl cellulose (TAC) resin film, but any of resin films can be preferably used for a transparent resin film of the present invention, as long as it has a transmittance of 80% at a visible range wavelength of 380-780 nm. Of these, a bi-axially stretching polyethylene terephthalate film, a bi-axially stretching polyethylene naphthalate film, a polyether sulfone film, a polycarbonate film are preferable in view of transparency, heat resistance, easy handling, strength and cost, but a bi-axially stretching polyethylene terephthalate film and a bi-axially stretching polyethylene naphthalate film are more preferable.

The transparent substrate employed in the present invention, on which an easy adhesion layer can be formed, is possible to be subjected to a surface treatment in order to secure wettability and adhesiveness. Commonly known techniques can be applied for the surface treatment and the easy adhesion layer. Examples of the surface treatment include surface activation treatments such as a corona discharge treatment, a flame treatment, a UV treatment, a high frequency treatment, a glow discharge treatment, an active plasma treatment and a laser treatment.

Further, the easy adhesion layer can be formed from polyester, polyamide, polyurethane, a vinyl based copolymer, a butadiene based copolymer, an acrylic copolymer, a vinylidene based copolymer, or an epoxy based copolymer. The easy adhesion layer may be composed of a single layer, but be composed of at least two layers in order to improve adhesion.

### [Pattern Formation]

Some kind of pattern formation is conducted to apply a transparent conductive film of the present invention to an electrode of an electronic device. Pattern formation is directly conducted by a printing method or an inkjet method, but after preparing a uniform transparent conductive film, the film having been subjected to a pattern forming treatment can be more efficiently manufactured, and the latter is more preferable than the former.

As the pattern forming treatment, usable are a method of forming patterns via a conventional photolithographic process; a method by which a layer containing metal nanowires of the present invention is uniformly formed on the negative pattern having been previously formed on a substrate by a photoresist to form patterns via a liftoff process; and a method by which a composition containing a metal nanowire remover is pattern-printed, followed by washing with water. Of these, the method by which a composition containing a metal nanowire remover is pattern-printed, followed by washing with water is the most preferable pattern forming method, since a process thereof is simple.

As the composition containing a metal nanowire remover, preferably usable is a bleaching fixer used for a developing treatment for a silver halide color photographic photosensitive material.

As a bleaching agent to be used in a bleaching fixer, commonly known bleaching agents are usable, but an organic complex salt of iron (III) (for example, an organic complex of each of aminopolycarboxylic acids), an organic acid such as a citric acid, a tartaric acid, a malic acid or the like, a persulfate, and hydrogen peroxide are preferable.

Of these, an organic complex salt of iron (III) is preferable in view of a rapid treatment and prevention of environmental pollution. An aminopolycarboxylic acid iron complex is specifically preferable. Examples of the aminopolycarboxylic acid and a salt thereof include an (SS)-ethylenediamine disaccinic acid, an N-(2-carboxylatoethyl)-L-aspartic acid, a β-aranine diacetic acid, methylimino diacetic acid, an ethylene diamine tetraacetic acid, a diethylene triamine penta acetic acid, a 1,3-diaminopropane tetraacetic acid, a propylene diamine tetraacetic acid, a nitrilotriacetic acid, a cyclohexane diamine tetraacetic acid, an imino diacetic acid, a glycol ether diamine tetraacetic acid, and a compound represented by Formula (I) or (II) disclosed in EP Patent No. 0789275. These compounds may be any of sodium, potassium, lithium, and an ammonium salt. Of these, compounds, as to an (SS)-ethylenediamine disaccinic acid, an N-(2-carboxylatoethyl)-L-aspartic acid, β-aranine diacetic acid, methylimino diacetate, an ethylene diamine tetraacetic acid, a 1,3-diaminopropane tetraacetic acid, and a methylimino diacetic acid, iron (III) thereof is preferable. These ferric ion complex salts may be used in a form of a complex, or ferric salt, for example, ferric sulfate, ferric chloride, ferric nitrate, ferric sulfate ammonium or ferric phosphate may be used together with chelating agents such as aminopolycarbonic acid to form a ferric ion complex salt in the solution. Further, chelating agents may be used, exceeding an amount needed to form a complex salt with a ferric ion. The aminopolycarboxylic acid iron complex of iron (III) has an addition amount of 0.01-1.0 mol/liter, preferably has an addition amount of 0.05-0.50 mol/liter, more preferably has an addition amount of 0.10-0.50 mol/liter, and still more preferably has an addition amount of 0.15-0.40 mol/liter.

Bleaching agents to be used for a bleaching fixer are commonly known fixing agents, namely, water soluble silver halide dissolving agents such as a thiosulfate like sodium thiosulfate and ammonium thiosulfate, a thiocyanate such as sodium thiocyanate and ammonium thiocyanate, thioether compounds such as ethylenebisglycolic acid, 3,6-dithia-1 and 8-octanediol, and thiourea, and these can be used singly or in combination with at least two kinds. Further, also usable is a special bleaching fixer obtained by using a fixing agent disclosed in Japanese Patent Publication No. 55-155354 in combination with a halide such as a large amount of potassium iodide. In the present invention, thiosulfate salt, specifically, thiosulfuric acid ammonium salt is preferably used. An amount of fixing agent per one liter is preferably 0.3-2.0 mot, and more preferably 0.5-1.0 mol.

The bleaching fixer used in the present invention preferably has a pH of 3-8, and more preferably has a pH of 4-7. In order to adjust the pH, a hydrochloric acid, a sulfuric acid, a nitric acid, bicarbonate, ammonia, potassium hydroxide, sodium hydroxide, sodium carbonate, or potassium carbonate may be added, if desired.

Various other kinds of a defoaming agent, a surfactant, or an organic solvent such as polyvinyl pyrrolidone or methanol can be contained in the bleaching fixer. The bleaching fixer preferably contains a sulfite ion releasing compound such as a sulfite (for example, sodium sulfite, potassium sulfite, and ammonium sulfite); a bisulfite (for example, ammonium bisulfite, sodium bisulfite, and potassium bisulfite); or a metabisulfite (for example, potassium metabisulfite, sodium metabisulfite, and ammonium metabisulfite) as a preserving agent, and an arylsulfinic acid such as a p-toluene sulfinic acid or an m-carboxybenzene sulfinic acid. Approximately 0.02-1.0 mol/liter of each of these compounds is preferably contained in conversion of sulfite ion or sulfinic acid ion.

As the preserving agent, also added is an ascorbic acid, a carbonyl bisulfite adduct, or a carbonyl compound in addition to the above-described. Further, a buffering agent, a chelating agent, a defoaming agent or a mildew-proofing agent may also added, if desired.

It is preferred that the material nanowire remover further contains a water-soluble binder. Usable examples of the water-soluble binder include an ethylene-vinyl alcohol copolymer, polyvinyl alcohol, sodium polyacrylate, carbohydrate and its derivative. As the carbohydrate and its derivative, provided are a water-soluble cellulose derivative and a water-soluble natural polymer. Examples of the water-soluble cellulose derivative include cellulose derivatives of methyl, hydroxyethyl, sodium carboxy methyl {being a sodium salt which is carboxymethyl cellulose (hereinafter, referred to as CMC)}, or carboxymethyl. Further, examples of the water-soluble natural polymer include starch, cornstarch, soluble starch, and dextrin. Of these, CMC is preferable, since it is easy to be dissolved. A molecular weight of the water-soluble binder in the present invention can be arbitrarily selected, depending on viscosity as needed.

Preferably usable examples of a method of pattern-printing a composition containing a metal nanowire remover include printing methods such as a letterpress (typographic) printing method, a porous (screen) printing method, a lithographic (offset) printing method, an intaglio (gravure) printing, a spray printing method, and an ink-jet printing method. Of these, an intaglio (gravure) printing, a spray printing method, and an ink-jet printing method are preferably usable. The composition containing a metal nanowire remover of the present invention is pattern-printed on the portion to become a non-pattern portion of a conductive layer of the present invention, and metal nanowires in the non-pattern portion are subsequently removed via a water washing treatment to form a pattern electrode.

### [Pattern Electrode]

Total light transmittance in pattern portions of a pattern electrode of the present invention is at least 60%; preferably at least 70%, and more preferably at least 80%. The total light transmittance can be measured by a commonly known method, employing a spectrophotometer.

An electrical resistance value in the pattern portion of the pattern electrode is preferably 10³ Ω/□ or less in terms of surface specific resistance; more preferably 10² Ω/□ or less; and most preferably 10 Ω/□ or less. The surface specific resistance can be measured in accordance with JIS K6911 or ASTM D257, and can be easily measured employing a commercially available surface resistance meter.

### [Washing Treatment]

Since a trouble is cased by dust or foreign matter in the case of a transparent electrode for an electronic device, a washing treatment is preferably conducted. Since an organic solar battery and so forth, foreign matter in size of several ten nanometers causes leakage specifically in the case of an organic EL, a washing treatment should be applied.

As a cleaning material, usable are ultrapure water obtained by removing fine particles via a filtration treatment, and solvents such as isopropyl alcohol, acetone and so forth. Further, commercially available cleaning agents such as CLEAN THROUGH KS-3030, and CLEAN THROUGH KS-3053 (produced by Kao Corporation) are also preferably usable.

### EXAMPLE

The present invention will be specifically described, referring to Examples, but the present invention is not limited thereto. Incidentally, “parts” and “%” described in the examples represent “parts by weight” and “% by weight” unless otherwise specified. In addition, silver nanowires are employed as nanowires in the present Examples.

### Example 1

### Preparation of Transparent Conductive Film TC-10

### Present Invention

The following auxiliary layer coating solution H-01 was extrusion-coated on the surface of a biaxially stretched PET film A4100 (produced by Toyobo Co., Ltd.), which has been subjected to easy adhesion processing so as to reach a crosslinking agent coating weight of 40 mg/m², followed by drying at 90° C. for 20 seconds. Subsequently, the following silver nanowire-containing solution AGW-1 as a coating solution containing metal nanowires was extrusion-coated so as to reach a silver coating weight of 80 mg/m², followed by drying at 115° C. for 10 seconds to obtain a transparent conductive film TC-10 of the present invention.

| | | |
|---|---|---|
| BECKAMINE M-3 (melamine based crosslinking agent, | 2.5 | g |
| produced by Dainippon Ink and Chemicals, Inc.) | | |
| BECKAMINE M-3 (catalyst, produced by Dainippon Ink | 0.25 | g |
| and Chemicals, Inc.) | | |
| Pure water | 497.25 | g |
| Isopropyl alcohol | 500 | g |

### (Preparation of AGW-1)

Referring to a method disclosed in Adv. Mater. 2002, 14, 833-837 for metal particles, EG (ethylene glycol, produced by Kanto Kagaku Chemical Co., Inc.) as a reducing agent, and PVP (polyvinyl pyrrolidone K30 having a molecular weight of 50,000, produced by International Specialty Products, Inc.) as a morphological control agent serving also as a protective colloid agent were used, particles were formed by separating a nucleus forming step from a particle growth step to prepare a silver nanowire dispersion. Each step will be described below.

### (Nucleus Forming Step)

While stirring 100 ml of EG maintained at 160° C. in a reaction vessel, 2.0 ml of a silver nitrate EG solution (a silver nitrate concentration of 0.1 mol/liter) were added into the system, spending one minute at a given flow rate, and subsequently, the resulting maintained at 60° C. for 10 minutes, was reduced to form silver nucleus particles. It was confirmed that the reaction solution appeared yellow color derived from surface plasmon absorption of silver particles in nanosize, and silver particles (nucleus particles) were formed via reduction of silver ions.

### (Particle Growth Step)

The reaction solution containing nucleus particles was maintained at 160° C. while stirring after completing the above-described nucleus forming step, and 100 ml of a silver nitrate EG solution (a silver nitrate concentration of 1.0×10⁻¹ mol/liter) and 100 ml of a PVP EG solution (a PVP concentration of 3.24 g/liter) were added at a constant flow rate, spending 120 minutes employing a double-jet method. When the reaction solution was sampled at intervals of 30 minutes to observe it with an electron microscope in the particle growth process, nucleus particles formed in the nucleus forming step were grown in the form of a wire along with elapse of time, and no formation of new particles were observed in the nucleus growth step. As to the terminally-obtained silver nanowire, a particle diameters in the long and short axes directions, of each of micrographed 300 silver nanowire particle images, were measured to obtain an arithmetic mean value. The average particle diameter in the short axis direction, and the average particle diameter in the long axis direction were 75 nm and 35 μm, respectively.

### (Desalination Water Washing Step)

After cooling the reaction solution after completion of the above-described particle forming step down to room temperature, a desalination water washing treatment was conducted employing a 0.2 μm ultrafiltration film. The resulting was further subjected to a water washing treatment, followed by drying to obtain silver nanowires.

### (Preparation of Dispersion)

Subsequently, they are dispersed again in ethanol to prepare silver nanowire dispersion AGW-1 (a silver nanowire content of 0.8% by weight).

Next, preparation of each of transparent conductive films TC-11-TC-21 will be described.

### (Preparation of Transparent Conductive Film TC-11) (Present Invention)

Transparent conductive film TC-11 of the present invention was prepared similarly to preparation of transparent conductive film TC-10, except that coating thickness of auxiliary layer coating solution H-01 was changed so as to give a crosslinking agent coating weight of 25 mg/m², and as a coating solution containing metal nanowires, AGW-1 was replaced by silver nanowire dispersion AGW-2 (a silver nanowire content of 0.8% by weight) prepared by dispersing again silver nanowires obtained after completing the desalination water washing step in preparation of the foregoing AGW-1 in 0.6% by weight of hydroxypropylmethyl cellulose 60SH-50 (Shin-Etsu Chemical Co., Ltd.).

### (Preparation of Transparent Conductive Film TC-12) (Present Invention)

Transparent conductive film TC-12 of the present invention was prepared similarly to preparation of transparent conductive film TC-11, except that auxiliary layer coating solution H-01 was replaced by the following H-02.

### (H-02)

| | | |
|---|---|---|
| DECONAL EX521 (crosslinking agent, | 1.5 | g |
| produced by Nagase ChemteX Corporation) | | |
| Ammonium sulfate | 0.05 | g |
| Pure water | 798.45 | g |
| Isopropyl alcohol | 200 | g |

### (Preparation of Transparent Conductive Film TC-13) (Present Invention)

Transparent conductive film TC-13 of the present invention was prepared similarly to preparation of transparent conductive film TC-11, except that auxiliary layer coating solution H-01 was replaced by the following H-03.

### (H-03)

| | | |
|---|---|---|
| DECONAL EX1410 (crosslinking agent, | 1.5 | g |
| produced by Nagase ChemteX Corporation) | | |
| Ammonium sulfate | 0.05 | g |
| Pure water | 798.45 | g |
| Isopropyl alcohol | 200 | g |

### (Preparation of Transparent Conductive Film TC-14) (Present Invention)

Transparent conductive film TC-14 of the present invention was prepared similarly to preparation of transparent conductive film TC-11, except that auxiliary layer coating solution H-01 was replaced by the following H-04.

### (H-04)

| | |
|---|---|
| SUMIJULE N3300 (crosslinking agent, | 1.5 g |
| produced by Sumika Bayer Urethane Co., Ltd.) | |
| Methylethyl ketone | 98.5 g |

### (Preparation of Transparent Conductive Film TC-15) (Present Invention)

Transparent conductive film TC-15 of the present invention was prepared similarly to preparation of transparent conductive film TC-11, except that auxiliary layer coating solution H-01 was replaced by the following H-05. In addition, DECONAL EX212 (crosslinking agent, produced by Nagase ChemteX Corporation) is insoluble in a solvent (water) for the silver nanowire layer.

### (H-05)

| | |
|---|---|
| DECONAL EX212 (crosslinking agent, | 1.5 g |
| produced by Nagase ChemteX Corporation) | |
| Methylethyl ketone | 998.5 g |

### (Preparation of Transparent Conductive Film TC-16) (Present Invention)

Transparent conductive film TC-16 of the present invention was prepared similarly to preparation of transparent conductive film TC-11, except that auxiliary layer coating solution H-01 was replaced by the following H-06.

### (H-06)

| | | |
|---|---|---|
| Aqueous 40% by weight solution | 3.75 | g |
| of glyoxal (crosslinking agent) | | |
| Ammonium sulfate | 0.05 | g |
| Pure water | 796.2 | g |
| Isopropyl alcohol | 200 | g |

### (Preparation of Transparent Conductive Film TC-17) (Present Invention)

Transparent conductive film TC-17 of the present invention was prepared similarly to preparation of transparent conductive film TC-11, except that auxiliary layer coating solution H-01 was replaced by the following H-07, and the crosslinking agent coating weight was set to 30 mg/m².

### (H-07)

| | | |
|---|---|---|
| DECONAL EX521 (crosslinking agent, | 1.5 | g |
| produced by Nagase ChemteX Corporation) | | |
| Ammonium sulfate | 0.05 | g |
| PVA-224 (polymer containing a group | 996.95 | g |
| reacted with a crosslinking agent, | | |
| produced by KUREHA Corp.) | | |

### Preparation of Transparent Conductive Film TC-20

### Comparative Example

Transparent conductive film TC-20 of a comparative example was prepared similarly to preparation of transparent conductive film TC-11, except that auxiliary layer coating solution H-01 was replaced by the following A-10, and the polymer coating weight was set to 15 mg/m².

### (A-10)

| | |
|---|---|
| PVA-224 (produced by KUREHA Corp.) | 1.5 g |
| Pure water | 998.5 g |

### Preparation of Transparent Conductive Film TC-21

### Comparative Example

Transparent conductive film TC-21 as a comparative example was prepared, similarly to preparation of TC-11, except that after no auxiliary layer coating solution H-01 was coated, and a silver nanowire layer was directly coated on the surface having been subjected to easy adhesion processing, of biaxially stretched PET film A4100 (produced by Toyobo Co., Ltd.) having been subjected to easy adhesion processing, followed by drying at 90° C. for 20 seconds, auxiliary layer coating solution H-01 was coated on the silver nanowire layer so as to give a crosslinking agent coating weight of 15 mg/m², subsequently followed by a heat treatment at 115° C. for 10 minutes.

### (Evaluation of Washing Resistance Property)

Surface resistivity of each transparent conductive film was measured with a resistivity meter LORESTA GP manufactured by DIA instruments Co., Ltd. Subsequently, as a washing treatment, a film was immersed in SEMICON CLEAN 56 (manufactured by Furuuchi Chemical Corp.) to conduct an ultrasonic washing treatment for 10 minutes employing an ultrasonic cleaner BRANSONIC 3510 J-MT (Emerson Japan, Ltd.). After drying surface resistivity was measured again, and the surface washing property was evaluated from a value obtained by surface resistivity before washing divided by surface resistivity after washing. A value of 0.5 or more is accepted, a value of 0.7 or more is preferable, and a value of 0.8 or more is preferable.

### (Evaluation of Conduction)

Each transparent conductive film is placed as current-measurable AFM, and conduction between a sample and a sample holder was acquired via use of silver paste, employing S-Image manufactured by SII NanoTechnology Inc. A voltage of −5 V was applied, and a region having a square, 80 μm on a side was scanned to measure a current image and a shape image in the region at the same time.

Pass: A current image corresponding to at least a part of metal nanowire is observed.
Fail: Current is hardly carried, and no current image corresponding to metal nanowire is observed.

Results are shown in Table 1.

TABLE 1

| Transparent | Washing | | |
|---|---|---|---|
| conductive | resistance | | |
| film No. | property | Conduction | Remarks |
| TC-10 | 0.65 | Pass | Present invention |
| TC-11 | 0.93 | Pass | Present invention |
| TC-12 | 0.91 | Pass | Present invention |
| TC-13 | 0.92 | Pass | Present invention |
| TC-14 | 0.85 | Pass | Present invention |
| TC-15 | 0.76 | Pass | Present invention |
| TC-16 | 0.85 | Pass | Present invention |
| TC-17 | 1 | Pass | Present invention |
| TC-20 | 0.01 or less | Pass | Comparative example |
| TC-21 | 0.9 | Fail | Comparative example |

In Table 1, transparent conductive films of the present invention exhibit excellent conduction and washing resistance property, and further, since a coating solution containing metal wires contains hydroxypropyl cellulose (a polymer having a group with which a crosslinking agent is reacted); the crosslinking agent is soluble in a solvent for the coating solution containing metal wires; and a solution containing the crosslinking agent contains PVA (a polymer having a group with which a crosslinking agent is reacted), it is understood that a washing resistance property is improved.

### Example 2

### Preparation of Organic EL Element

Next, operation was conducted under the clean environment.

Employing a polyester mesh (255T, produced by Mitani Micronics Co., Ltd.) for screen printing in which the opposite printing pattern was formed with respect to 10 mm stripe-shaped pattern, viscosity of metal nanowire remover BF-1 was adjusted to 10000 cp by using carboxymethyl cellulose Na (C5013, produced by SIGMA-ALDRICH Co.; hereinafter, abbreviated as CMC) for each transparent conductive film prepared similarly to Example 1, and screen printing was conducted on the silver nanowire coating layer so as to give a coating layer thickness of 30 μm. Standing for one minute after printing, a water washing treatment with running water was carried out, and then pattern electrodes were prepared.

### <Preparation of Metal Nanowire Remover BF-1>

| | |
|---|---|
| Ethylene diamine tetraacetic acid | 60 g |
| ferric sulfate ammonium | |
| Ethylene diamine tetraacetic acid | 2 g |
| Sodium metabisulfite | 15 g |
| Ammonium thiosulfate | 70 g |
| Maleic acid | 5 g |

Pure water was added to make one liter, and a sulfuric acid or ammonia water was added to adjust pH to 5.5 to prepare metal nanowire remover BF-1.

Subsequently, a film was immersed in CLEAN THROUGH KS-3030 (Kao Corporation) and subjected to an ultrasonic washing treatment for 10 minutes, and washed with running water for 3 minutes by a water washing treatment.

The following layer was formed on a transparent conductive film having been subjected to this washing treatment to prepare an organic EL element.

### <Formation of Hole Injection Layer Serving as Planar Electrode Layer>

CLEVIOS D AI4083 {poly(3,4-ethylene dioxythiophene)/poly styrene sulfonic acid, produced by H. C. Starck Ltd.} as a hole injection material was coated with a spin coating device, followed by drying at 80° C. for 60 minutes to form a hole injection layer having a thickness of 300 nm. In addition, this hole injection layer serves as a planar electrode layer to carry electricity to window portions of silver nanowires.

### <Formation of Hole Transport Layer>

A hole transport layer forming coating solution in which 4,4′-bis[N-(1-naphtyl)-N-phenylamino]biphenyl (NPD) as a hole transport material was dissolved in 1,2-dichloroethylene so as to produce 1% by weight of the hole transport material was coated on the hole transport layer by a spin coating device, followed by 80° C. for 60 minutes to form a hole transport layer having a thickness of 40 nm.

### <Formation of Emission Layer>

An emission layer forming coating solution, in which the following Btp₂Ir (acac) as a red dopant, Ir(ppy)₃ as a green dopant, and Fir (pic)₃ as a blue dopant were mixed so as to give a content of 1% by weight, a content of 2% by weight and a content of 3% by weight, respectively, based on polyvinyl carbazole (PVK) as a host material, and dissolved in 1,2-dichloroethane in such a way that the total solid content of PVK and 3 kinds of dopants becomes 1% by weight, was coated on each film where a hole transport layer was formed, by a spin coating device.

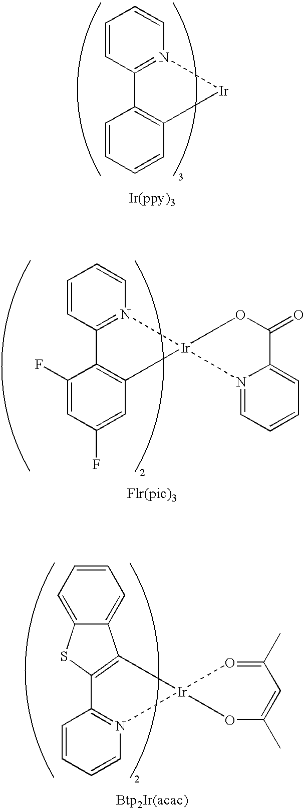

### <Formation of Electron Transport Layer>

LiF as an electron transport layer forming material was evaporated on the resulting emission layer at a vacuum degree of 5×10⁻⁴ Pa to form an electron transport layer having a thickness of 0.5 nm.

### <Formation of Cathode Electrode>

A1 was evaporated on the resulting electron transport layer at a vacuum degree of 5×10⁻⁴ Pa to form a cathode electrode having a thickness of 100 nm.

### <Formation of Sealing Film>

A 300 nm thick Al₂O₃ was evaporated on a polyethylene terephthalate substrate to prepare a flexible sealing member.

An adhesive was coated around a cathode electrode except end portions in such a way that externally taken-out terminals of an anode electrode and a cathode electrode were formed, and the adhesive was cured via heat treatment after attaching the foregoing flexible sealing member.

In addition, In the case of TC-20 as a comparative example, since a silver nanowire layer was peeled via washing with water in a pattern forming treatment, no element was formed.

A direct current voltage was applied to each organic EL element employing Source-Measure Unit 2400 Type manufactured by KEITHLEY Instruments, Inc to produce light emission. When TC-10-TC-17 (transparent conductive films of the present invention) were used, light emission was produced at a voltage of 10 V or less, but when TC-21 (a transparent conductive film of a comparative example) was used, no light emission was produced even at a voltage of 10 V.

As is clear from the above-described results, it is to be understood that an organic EL element fitted with a transparent conductive film exhibiting reduced manufacturing cost and reduced environmental load is possible to produce light emission.

### EFFECT OF THE INVENTION

Provided can be a transparent conductive film exhibiting high conductivity together with excellent transparency, and also exhibiting film strength tolerant to a washing treatment and a pattern forming treatment while maintaining conduction to an electronic device layer formed on an transparent conductive layer.

What is claimed is:

1. A method of manufacturing a transparent conductive film comprising a transparent substrate and provided thereon, a transparent conductive layer comprising a metal nanowire, comprising the steps of:
forming a layer comprising a crosslinking agent on the substrate,
coating a coating solution comprising a metal nanowire onto the layer comprising the crosslinking agent,
drying the coating solution, and
conducting a treatment by which the crosslinking agent is reacted.

2. The method of claim 1,
wherein the treatment is a heat treatment.

3. The method of claim 1,
wherein the coating solution comprises a polymer comprising a group capable of conducting reaction with the crosslinking agent.

4. The method of claim 1,
wherein the layer comprising the crosslinking agent comprises a polymer comprising a group capable of conducting reaction with the crosslinking agent.

5. The method of claim 1,
wherein the crosslinking agent is soluble in a solvent for the coating solution.

6. The method of claim 1, comprising the step of:
pattern-forming the transparent conductive layer via a pattern forming treatment.

7. The method of claim 1, comprising the step of:
conducting a washing treatment for the transparent conductive layer.

8. A transparent conductive film comprising a transparent substrate and provided thereon, a layer comprising a crosslinking agent, and a layer comprising a nanowire, further provided on the layer comprising a crosslinking agent.

9. A transparent conductive film prepared by the method of manufacturing a transparent conductive film of claim 1.

10. A transparent electrode comprising electronic device patterns of the transparent conductive film of claim 8.

11. A transparent electrode comprising electronic device patterns of the transparent conductive film of claim 9.
